(19) United States
(12) Patent Application Publication
(10) Pub. No.: US 2025/0047073 A1
(43) Pub. Date: Feb. 6, 2025

(54) VERTICAL CAVITY LIGHT-EMITTING ELEMENT

(71) Applicant: STANLEY ELECTRIC CO., LTD., Meguro-ku, Tokyo (JP)

(72) Inventors: Takanobu AKAGI, Tokyo (JP); Masaru KURAMOTO, Tokyo (JP)

(73) Assignee: STANLEY ELECTRIC CO., LTD., Meguro-ku, Tokyo (JP)

(21) Appl. No.: 18/716,893

(22) PCT Filed: Nov. 22, 2022
(86) PCT No.: PCT/JP2022/043105

§ 371 Date: Jun. 5, 2024

(30) Foreign Application Priority Data
Dec. 7, 2021 (JP) 2021-198295

(51) Int. Cl. H01S 5/183; H01S 5/343

(52) U.S. Cl. CPC H01S 5/18377; H01S 5/18308; H01S 5/34333

(57) ABSTRACT

A vertical cavity light-emitting element includes a gallium-nitride-based semiconductor substrate, a first multilayer reflector on the substrate, a semiconductor structure layer that includes an active layer made of a nitride semiconductor, a second multilayer reflector that is on the semiconductor structure layer and constitutes a resonator between the first and second multilayer reflectors, and a current confinement structure formed between the first and second multilayer reflectors. The first multilayer reflector is made by an In-containing nitride semiconductor layer containing In in composition and an In-free nitride semiconductor layer including no In being alternately laminated. The current confinement structure concentrates a current in one region of the active layer. An uppermost layer of the first multilayer reflector is the In-containing nitride semiconductor layer, and a region along an upper surface of the In-containing nitride semiconductor layer of the uppermost layer has a higher hydrogen impurity concentration than other regions.

### TECHNICAL FIELD

The present invention relates to a vertical cavity light-emitting element, such as a vertical cavity surface emitting laser (VCSEL).

### BACKGROUND ART

Conventionally, as one of semiconductor lasers, there has been known a vertical cavity-type semiconductor surface emitting laser (hereinafter also simply referred to as a surface emitting laser) including a semiconductor layer that emits light by application of voltage and multilayer reflectors opposed to one another with the semiconductor layer interposed therebetween. For example, Patent Document 1 discloses a vertical cavity-type semiconductor laser including an n-electrode and a p-electrode connected to an n-type semiconductor layer and a p-type semiconductor layer, respectively.
Patent Document 1: JP-A-2017-98328

### DISCLOSURE OF THE INVENTION

### Problems to be Solved by the Invention

For example, in a vertical cavity light-emitting element, such as a surface emitting laser, an optical resonator is formed by opposed multilayer reflectors. For example, inside the surface emitting laser, when a voltage is applied to a semiconductor layer through electrodes, a light emitted from the semiconductor layer resonates inside the optical resonator, which generates laser light.

In such a vertical cavity light-emitting element, a stress is generated due to differences in lattice constants between the multilayer reflector and the semiconductor layer including an active layer disposed on the multilayer reflector, or between respective layers included in the semiconductor layer. A thermal stress is generated inside the vertical cavity light-emitting element due to heat emitted from the active layer when the vertical cavity light-emitting element is driven.

In the vertical cavity light-emitting element, due to such a stress, one of problems is that damage such as dislocations occurs in the active layer and the surrounding semiconductor layers that serve as a path for a current to the active layer, resulting in deterioration of them and reduced durability.

The present invention has been made in consideration of the above-described points, and it is an object of the present invention to provide a vertical cavity light-emitting element having a high durability by reducing deterioration of a semiconductor layer including an active layer.

### Solutions to the Problems

A vertical cavity light-emitting element according to the present invention includes a gallium-nitride-based semiconductor substrate, a first multilayer reflector, a semiconductor structure layer, a second multilayer reflector, and a current confinement structure. The first multilayer reflector is formed on the substrate. The first multilayer reflector is made by an In-containing nitride semiconductor layer containing In in composition and an In-free nitride semiconductor layer including no In being alternately laminated. The semiconductor structure layer includes a first semiconductor layer, an active layer, and a second semiconductor layer. The first semiconductor layer is made of a nitride semiconductor having a first conductivity type formed on the first multilayer reflector. The active layer is made of a nitride semiconductor formed on the first semiconductor layer. The second semiconductor layer is formed on the active layer and made of a nitride semiconductor having a second conductivity type opposite to the first conductivity type. The second multilayer reflector is formed on the semiconductor structure layer. The second multilayer reflector constitutes a resonator between the first multilayer reflector and the second multilayer reflector. The current confinement structure is formed between the first multilayer reflector and the second multilayer reflector. The current confinement structure concentrates a current in one region of the active layer. A region along an upper surface of the In-containing nitride semiconductor layer in an uppermost layer of the In-containing nitride semiconductor layer of the first multilayer reflector has a higher hydrogen impurity concentration than other regions.

### BRIEF DESCRIPTION OF THE DRAWINGS

FIG. 1 is a perspective view of a surface emitting laser of Embodiment 1.

FIG. 2 is a cross-sectional view of the surface emitting laser of Embodiment 1.

FIG. 3 is SIMS measurement results near an upper surface of an AlInN layer of an uppermost layer in a first multilayer reflector.

FIG. 4 is a cross-sectional view of a laser device using the surface emitting laser of Embodiment 1.

FIG. 5 is a TEM image near the upper surface of the AlInN layer of the uppermost layer in the first multilayer reflector.

FIG. 6 is an enlarged view of a part of the TEM image in FIG. 5.

FIG. 7 is a cross-sectional view of a surface emitting laser of a modification.

### DESCRIPTION OF PREFERRED EMBODIMENTS

The following describes embodiments of the present invention in detail. While, in the following description, a description will be made using a semiconductor surface emitting laser element as an example, the present invention is applicable not only to a surface emitting laser but also to various kinds of vertical cavity light-emitting elements, such as a vertical cavity-type light-emitting diode.

### Embodiment 1

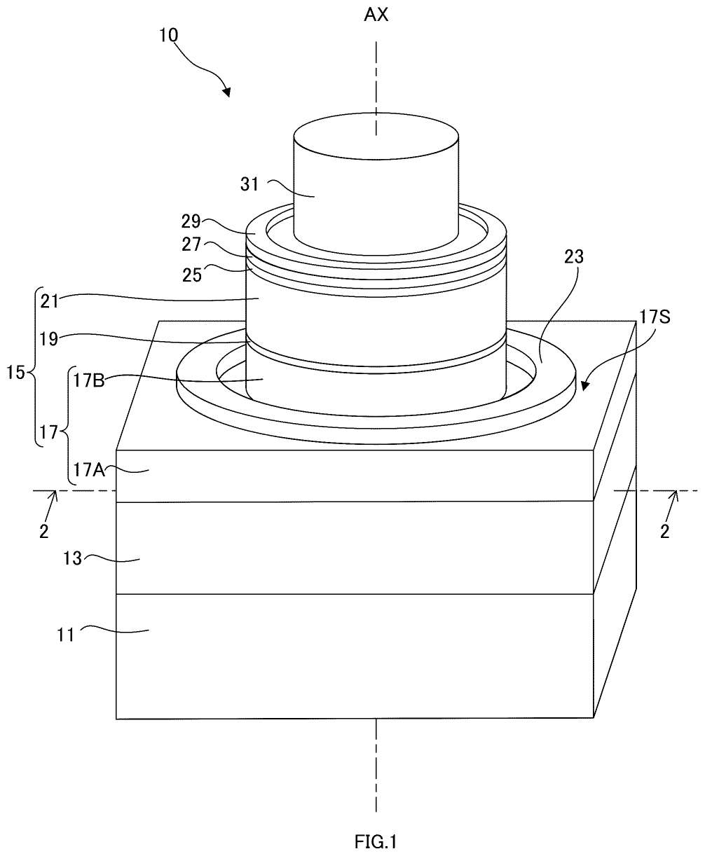

FIG. 1 is a perspective view of a vertical cavity surface emitting laser (VCSEL, hereinafter also simply referred to as a surface emitting laser) 10 according to Embodiment 1.

A substrate 11 is a gallium-nitride-based semiconductor substrate, for example, a GaN substrate. The substrate 11 is a so-called c-plane substrate in which the c-plane is exposed on an upper surface. The substrate 11 is, for example, a substrate with a rectangular upper surface shape.

A first multilayer reflector 13 is a semiconductor multilayer reflector made of a semiconductor layer that has been grown on the substrate 11. The first multilayer reflector 13 is formed by alternately laminating a semiconductor film having a composition of AlInN and a semiconductor film having a GaN composition with a refractive index higher than that of the semiconductor film having an AlInN composition. In other words, the first multilayer reflector 13 is a distributed Bragg reflector (DBR) made of a semiconductor material.

A semiconductor structure layer 15 is a laminated structure made of a plurality of semiconductor layers formed on the first multilayer reflector 13. The semiconductor structure layer 15 includes an n-type semiconductor layer (a first semiconductor layer) 17 formed on the first multilayer reflector 13, a light-emitting layer (or an active layer) 19 formed on the n-type semiconductor layer 17, and a p-type semiconductor layer (a second semiconductor layer) 21 formed on the active layer 19.

The n-type semiconductor layer 17 as a first conductivity type semiconductor layer is a semiconductor layer formed on the first multilayer reflector 13. The n-type semiconductor layer 17 is a semiconductor layer that has the GaN composition and is doped with Si as n-type impurities. The n-type semiconductor layer 17 includes a prismatic-shaped lower portion 17A and a column-shaped upper portion 17B thereon (The n-type semiconductor layer 17 has a mesa shape and includes the lower portion 17A having a planar shape similar to that of an upper surface of the first multilayer reflector 13 and a mesa-shaped upper portion 17B disposed thereon). Specifically, for example, the n-type semiconductor layer 17 includes the column-shaped upper portion 17B projecting from an upper surface 17S of the prismatic-shaped lower portion 17A. In other words, the n-type semiconductor layer 17 has a mesa-shaped structure including the upper portion 17B.

The active layer 19 is a layer that is formed on the upper portion 17B of the n-type semiconductor layer 17 and has a quantum well structure including a well layer having an InGaN composition and a barrier layer having the GaN composition. In the surface emitting laser 10, a light is generated in the active layer 19.

The p-type semiconductor layer 21 as a second conductivity type semiconductor layer is a semiconductor layer having the GaN composition formed on the active layer 19. The p-type semiconductor layer 21 is doped with Mg as p-type impurities.

An n-electrode 23 is a metal electrode disposed on the upper surface 17S of the lower portion 17A of the n-type semiconductor layer 17 and electrically connected to the n-type semiconductor layer 17. The n-electrode 23 is formed into a ring shape so as to surround the upper portion 17B of the n-type semiconductor layer 17. The n-electrode 23 is electrically in contact with the n-type semiconductor layer 17 and forms a first electrode layer that supplies a current from an outside to the semiconductor structure layer 15.

An insulating layer 25 is a layer made of an insulator formed on the p-type semiconductor layer 21. The insulating layer 25 is formed of, for example, a substance having a refractive index lower than that of a material forming the p-type semiconductor layer 21, such as SiO₂. The insulating layer 25 is formed into a ring shape on the p-type semiconductor layer 21 and has an opening (not illustrated) that exposes the p-type semiconductor layer 21 in a central portion.

A transparent electrode 27 is a metal oxide film having a translucency formed on an upper surface of the insulating layer 25. The transparent electrode 27 covers the entire upper surface of the insulating layer 25 and an entire upper surface of the p-type semiconductor layer 21 exposed from the opening formed in the central portion of the insulating layer 25. As a metal oxide film forming the transparent electrode 27, for example, ITO or IZO having a translucency relative to the emitted light from the active layer 19 can be used.

A p-electrode 29 is a metal electrode formed on the transparent electrode 27. The p-electrode 29 is electrically connected to the upper surface of the p-type semiconductor layer 21 exposed from the above-described opening of the insulating layer 25 via the transparent electrode 27. The transparent electrode 27 and the p-electrode 29 form a second electrode layer that is electrically in contact with the p-type semiconductor layer 21 and supply a current from the outside to the semiconductor structure layer 15. In this embodiment, the p-electrode 29 is formed on an upper surface of the transparent electrode 27 in a ring shape along an outer edge of the upper surface.

A second multilayer reflector 31 is a column shaped multilayer reflector formed in a region surrounded by the p-electrode 29 on the upper surface of the transparent electrode 27. The second multilayer reflector 31 is a dielectric multilayer reflector in which low refractive-index dielectric films made of SiO₂ and high refractive-index dielectric films made of Nb₂O₅ having a refractive index higher than that of the low refractive-index dielectric film are alternately laminated. In other words, the second multilayer reflector 31 is a distributed Bragg reflector (DBR) made of a dielectric material.

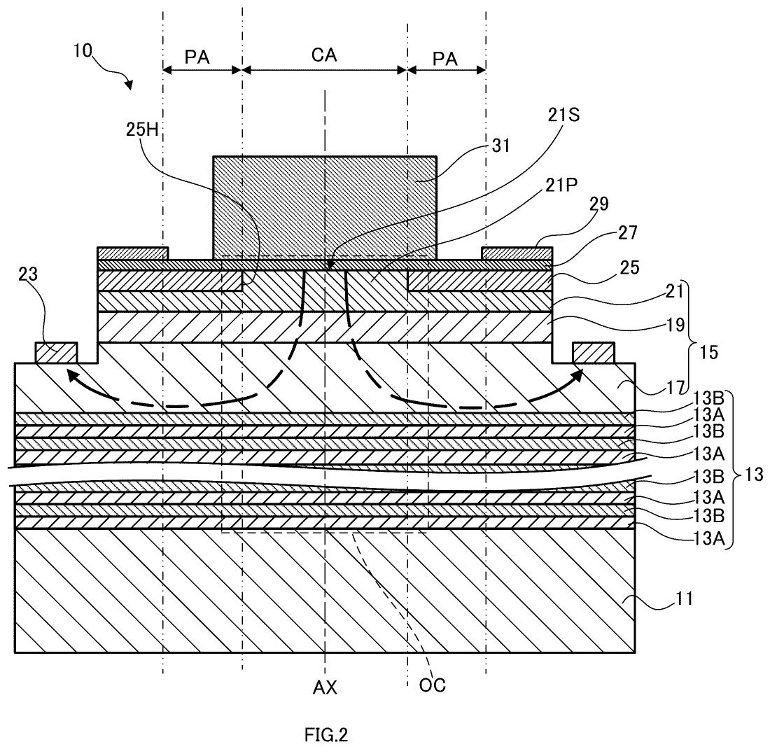

FIG. 2 is a cross-sectional view taken along the line 2-2 in FIG. 1. As described above, the surface emitting laser 10 includes the substrate 11 that is the GaN substrate, and the first multilayer reflector 13 is formed on the substrate 11. An AR coating may be applied on a lower surface of the substrate 11.

The first multilayer reflector 13 is formed by disposing a buffer layer (not illustrated) having the GaN composition on an upper surface of the substrate 11, forming a film of a low refractive-index semiconductor film 13A made of the above-described AlInN on the buffer layer, and then alternately forming films of a high refractive-index semiconductor film 13B made of GaN and the low refractive-index semiconductor film 13A in this order. An uppermost layer of the first multilayer reflector 13 is the high refractive-index semiconductor film 13B made of GaN.

For example, in this embodiment, the first multilayer reflector 13 is made of 41 pairs of AlInN layers/GaN layers laminated on a GaN base layer of 1 μm thickness formed on the upper surface of the substrate 11. In other words, the first multilayer reflector 13 is a laminated body made of 41 layers of AlInN layers and 41 layers of GaN layers, which are alternately laminated with one another, and its lowermost layer is the AlInN layer, and its uppermost layer is the GaN layer.

In further other words, the first multilayer reflector 13 is a laminated body made by an In-containing nitride semiconductor layers containing In in composition and an In-free nitride semiconductor layers containing no In being alternately laminated.

In the layer formed uppermost among the low refractive-index semiconductor films 13A that are the AlInN layers of the first multilayer reflector 13, a portion with a high concentration of hydrogen, which is an impurity, is formed in a region along its upper surface, in other words, in a region along an interface with the GaN layer of the high refractive-index semiconductor film 13B, which is the uppermost layer of the first multilayer reflector 13. In other words, in the region along the upper surface of the layer formed uppermost among the AlInN layers of the first multilayer reflector 13, the hydrogen impurity concentration is higher than the other regions, that is, the central portion in the thickness direction of the AlInN layer. Furthermore, this hydrogen impurity concentration is higher than that of the GaN layer formed immediately thereon, that is, the high refractive-index semiconductor film 13B and the n-type semiconductor layer 17 described later.

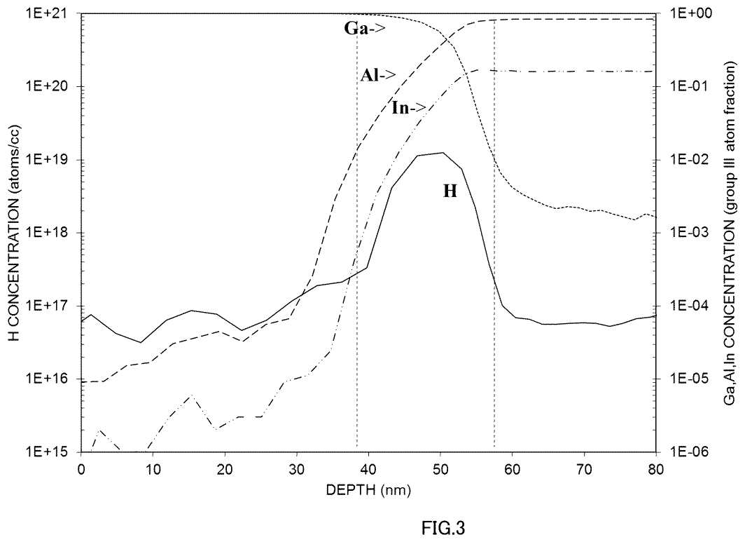

FIG. 3 is a graph of measurement results by a method of Secondary Ion Mass Spectrometry (SIMS) that indicates each density (atoms/cc) of Aluminum (Al), Indium (In), hydrogen (H), and Gallium (Ga) on the further upper surface of the uppermost layer of the low refractive-index semiconductor film 13A in the first multilayer reflector 13, that is, the region along the interface with the GaN layer of the high refractive-index semiconductor film 13B. In this graph, the horizontal axis is the depth in the layer thickness direction, and the left vertical axis is the density of hydrogen, and the right vertical axis is the densities of gallium, aluminum, and indium.

Referring to FIG. 3, in the low refractive-index semiconductor film 13A as the uppermost layer of the first multilayer reflector 13, it can be seen that in the region along the interface with the high refractive-index semiconductor film 13B (the region sandwiched between the broken lines in FIG. 3), a portion where the hydrogen concentration exceeds 1E18/cm³ is formed. The hydrogen concentration is 1E17/cm³ or less in the region away from the interface of the low refractive-index semiconductor film 13A and the GaN layer formed immediately thereon, that is, the region away from the interface of the high refractive-index semiconductor film 13B, and a concentration difference of 10 times or more is generated.

When a portion with a high hydrogen impurity concentration is present in the low refractive-index semiconductor film 13A having the AlInN composition, it has been found by the inventors of this application that basal plane dislocations (hereinafter also simply referred to as plane dislocations) are more likely to occur in portions where the hydrogen impurity concentration is high when stress is applied to the low refractive-index semiconductor film 13A. In other words, in the surface emitting laser 10 of this embodiment, it has been found that the basal plane dislocations are more likely to occur due to a stress load in a region along an upper surface of the low refractive-index semiconductor film 13A of the first multilayer reflector 13.

As described above, the semiconductor structure layer 15 is formed on the first multilayer reflector 13. The semiconductor structure layer 15 is a laminated body made by the n-type semiconductor layer 17, the active layer 19, and the p-type semiconductor layer 21, which are formed in this order. At the center portion on the upper surface of the p-type semiconductor layer 21, a projecting portion 21P projecting upward is formed.

The insulating layer 25 is formed to cover a region of the upper surface of the p-type semiconductor layer 21 other than the projecting portion 21P. The insulating layer 25 is made of a material having a refractive index lower than that of the p-type semiconductor layer 21 as described above. The insulating layer 25 has an opening 25H that exposes the projecting portion 21P. For example, the opening 25H and the projecting portion 21P have similar shapes, and an inner surface of the opening 25H is in contact with an outer surface of the projecting portion 21P.

The transparent electrode 27 is formed to cover upper surfaces of the insulating layer 25 and the projecting portion 21P exposed from the opening 25H of the insulating layer 25. That is, the transparent electrode 27 is electrically in contact with the p-type semiconductor layer 21 in a region exposed by the opening 25H on the upper surface of the p-type semiconductor layer 21. In other words, the region exposed through the opening 25H on the upper surface of the p-type semiconductor layer 21 is an electrical contact surface 21S, which provides an electrical contact between the p-type semiconductor layer 21 and the transparent electrode 27.

The p-electrode 29 is a metal electrode as described above and formed along the outer edge of an upper surface of the transparent electrode 27. That is, the p-electrode 29 is electrically in contact with the transparent electrode 27. Accordingly, the p-electrode 29 is electrically in contact with or connected to the p-type semiconductor layer 21 via the transparent electrode 27 on the electrical contact surface 21S exposed by the opening 25H on the upper surface of the p-type semiconductor layer 21.

The second multilayer reflector 31 is formed on the upper surface of the transparent electrode 27 and in a region on the opening 25H of the insulating layer 25, in other words, a region on the electrical contact surface 21S, that is, at the central portion of the upper surface of the transparent electrode 27. A lower surface of the second multilayer reflector 31 is opposed to the upper surface of the first multilayer reflector 13 with the transparent electrode 27 and the semiconductor structure layer 15 interposed therebetween. The arrangement of the first multilayer reflector 13 and the second multilayer reflector 31 forms a resonator OC that resonates a light emitted from the active layer 19 with the first multilayer reflector 13 and the second multilayer reflector 31.

In the surface emitting laser 10, the first multilayer reflector 13 has a reflectivity slightly lower than that of the second multilayer reflector 31. Accordingly, a part of the light resonated between the first multilayer reflector 13 and the second multilayer reflector 31 transmits through the first multilayer reflector 13 and the substrate 11 to be taken out to the outside.

Here, an operation of the surface emitting laser 10 will be described. In the surface emitting laser 10, when a voltage is applied between the n-electrode 23 and the p-electrode 29, a current flows in the semiconductor structure layer 15 as indicated by the one-dot chain bold line in FIG. 2, and a light is emitted from the active layer 19. The light emitted from the active layer 19 is repeatedly reflected between the first multilayer reflector 13 and the second multilayer reflector 31 to reach a resonant state (that is, laser oscillate).

In the surface emitting laser 10, the current is injected into the p-type semiconductor layer 21 only from a portion exposed by the opening 25H, that is, the electrical contact surface 21S. Since the p-type semiconductor layer 21 is considerably thin, the current does not diffuse in an in-plane direction, that is, in a direction along a surface of the semiconductor structure layer 15 in the p-type semiconductor layer 21.

Accordingly, in the surface emitting laser 10, the current is supplied only into a region immediately below the electrical contact surface 21S defined by the opening 25H in the active layer 19, and the light is emitted only from this region. That is, in the surface emitting laser 10, the opening 25H has a current confinement structure that restricts a supply range of the current in the active layer 19.

In other words, in the surface emitting laser 10, the current confinement structure that confines the current such that the current flows only into a central region CA, which is a columnar region with the electrical contact surface 21S as a bottom surface in the active layer 19, that is, concentrates the current into one region of the active layer is formed between the first multilayer reflector 13 and the second multilayer reflector 31. The central region CA including the region through which the current flows inside the active layer 19 is defined by the electrical contact surface 21S.

As described above, in this embodiment, the first multilayer reflector 13 has a reflectivity lower than that of the second multilayer reflector 31. Accordingly, a part of the light resonated between the first multilayer reflector 13 and the second multilayer reflector 31 transmits through the first multilayer reflector 13 and the substrate 11 to be taken out to the outside. Thus, the surface emitting laser 10 emits the light in the direction perpendicular to the lower surface of the substrate 11 and the in-plane directions of the respective layers of the semiconductor structure layer 15, from the lower surface of the substrate 11. In other words, the lower surface of the substrate 11 is a light-emitting surface of the surface emitting laser 10.

The electrical contact surface 21S of the p-type semiconductor layer 21 of the semiconductor structure layer 15 and the opening 25H of the insulating layer 25 define a luminescence center as the center of a light emission region in the active layer 19 and define a center axis (a luminescence center axis) AX of the resonator OC. The center axis AX of the resonator OC passes through the center of the electrical contact surface 21S of the p-type semiconductor layer 21 and extends along the direction perpendicular to the in-plane direction of the semiconductor structure layer 15.

The light emission region of the active layer 19 is, for example, a region having a predetermined width through which a light having a predetermined intensity or more is emitted inside the active layer 19, and its center is the luminescence center. For example, the light emission region of the active layer 19 is a region to which a current having a predetermined density or more is injected inside the active layer 19, and its center is the luminescence center. A straight line that is perpendicular to the upper surface of the substrate 11 or the in-plane directions of the respective layers of the semiconductor structure layer 15 and passes through the luminescence center is the center axis AX.

The luminescence center axis AX is a straight line that extends along a resonator length direction of the resonator OC constituted of the first multilayer reflector 13 and the second multilayer reflector 31. The center axis AX corresponds to an optical axis of a laser light emitted from the surface emitting laser 10.

Here, an exemplary configuration of the respective layers of the first multilayer reflector 13, the semiconductor structure layer 15, and the second multilayer reflector 31 in the surface emitting laser 10 will be described. In this embodiment, the first multilayer reflector 13 is made of a GaN base layer of 1 μm thickness and 41 pairs of AlInN layers (50 nm) and GaN layers (45 nm) formed on the upper surface of the substrate 11.

The n-type semiconductor layer 17 is the GaN layer having a layer thickness of 558 nm. The active layer 19 is made of an active layer in a multiple quantum well structure in which 5 pairs of GaInN layers of 4 nm and GaN layers of 5 nm are laminated. On the active layer 19, an electronic barrier layer of AlGaN doped with Mg is formed, and the p-type semiconductor layer 21 made of p-GaN layer of 50 nm is formed on the electronic barrier layer. The second multilayer reflector 31 is a lamination of 10.5 pairs of Nb₂O₅ and SiO₂. The resonant wavelength in this case was 440 nm.

The insulating layer 25 is the layer made of SiO₂ of 20 nm. In other words, the projecting portion 21P on the upper surface of the p-type semiconductor layer 21 projects 20 nm from the peripheral area. That is, the p-type semiconductor layer 21 has a layer thickness of 50 nm at the projecting portion 21P and has a layer thickness of 30 nm in the other region. The upper surface of the insulating layer 25 is configured to be arranged at a height position identical to the upper surface of the projecting portion 21P of the p-type semiconductor layer 21. These configurations describe merely one example.

The following describes optical features of an inside of the surface emitting laser 10. As described above, in the surface emitting laser 10, the insulating layer 25 has a refractive index lower than that of the p-type semiconductor layer 21. Between the first multilayer reflector 13 and the second multilayer reflector 31, the layer thicknesses of the active layer 19 and the n-type semiconductor layer 17 are the same at any positions in the plane as long as they are in the same layer.

Accordingly, an equivalent refractive index (an optical distance between the first multilayer reflector 13 and the second multilayer reflector 31, which corresponds to a resonant wavelength) inside the resonator OC formed between the first multilayer reflector 13 and the second multilayer reflector 31 of the surface emitting laser 10 differs in the column-shaped central region CA with the electrical contact surface 21S as a bottom surface and in a pipe-shaped peripheral region PA around the central region CA due to a difference in refractive indexes between the p-type semiconductor layer 21 and the insulating layer 25.

Specifically, between the first multilayer reflector 13 and the second multilayer reflector 31, the equivalent refractive index in the peripheral region PA is lower than the equivalent refractive index in the central region CA, that is, an equivalent resonant wavelength in the central region CA is smaller than the equivalent resonant wavelength in the peripheral region PA. Where the light is emitted in the active layer 19 is the region immediately below the opening 25H and the electrical contact surface 21S. That is, the light emission region where the light is emitted in the active layer 19 is a portion overlapping with the central region CA in the active layer 19, in other words, a region overlapping with the electrical contact surface 21S in the top view.

Thus, in the surface emitting laser 10, the central region CA including the light emission region of the active layer 19 and the peripheral region PA, which surrounds the central region CA and has the refractive index lower than that of the central region CA, are formed. This reduces an optical loss caused by diffusion (radiation) of a standing wave within the central region CA into the peripheral region PA. That is, a large quantity of light remains in the central region CA and the laser light is taken out to the outside in this state. Accordingly, the large quantity of light concentrates in the central region CA in the peripheral area of the luminescence center axis AX of the resonator OC to allow generating and emitting the laser light with high output power and high density.

[Structure of Laser Device 100 mounted with Surface Emitting Laser 10 Element]

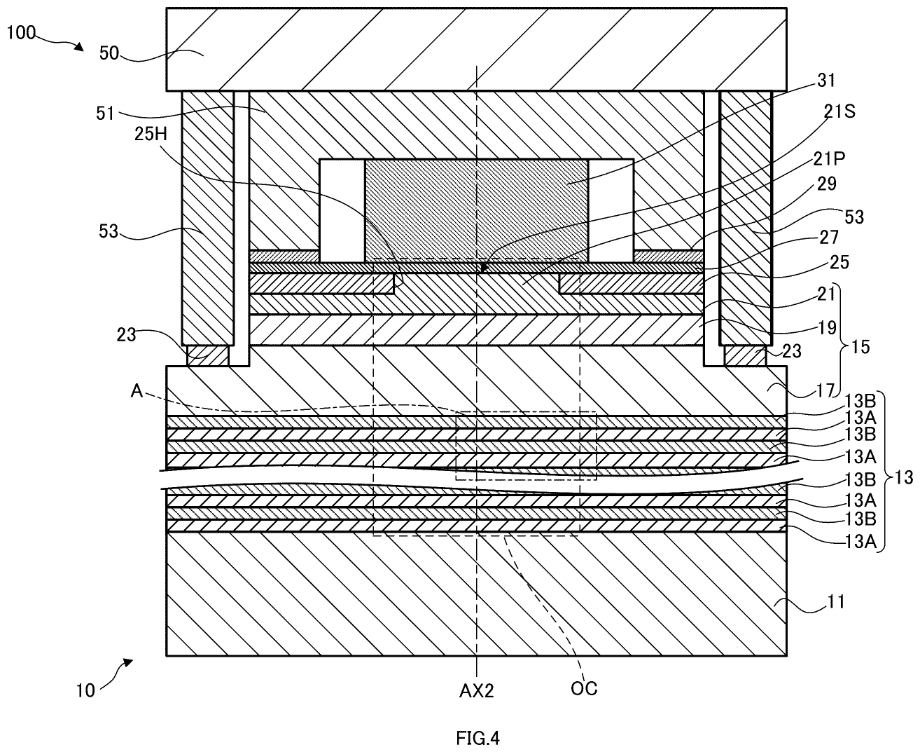

In FIG. 4, a cross-sectional view of the laser device 100 where the surface emitting laser 10 is mounted to a support substrate 50 is illustrated. The cross-sectional view in FIG. 4 indicates a cross-section taken along the cross-sectional line identical to that of the cross-section indicated in the cross-sectional view illustrated in FIG. 2.

In the laser device 100, the surface emitting laser 10 is bonded to the support substrate 50 by bonding portions 51 and 53 formed by eutectic crystal of AuSn. The bonding portion 51 bonds the p-electrode 29 and the second multilayer reflector 31 to the support substrate 50. The bonding portion 51 is formed so as to cover an upper surface of the p-electrode 29 and an upper surface of the second multilayer reflector 31. A wiring (not illustrated) for supplying a current to the p-electrode is formed in a portion of a surface of the support substrate 50 that the bonding portion 51 covers.

The bonding portion 53 bonds the n-electrode 23 to the support substrate 50. The bonding portion 53 is separated from the bonding portion 51 so as to be insulated from the bonding portion 51. A wiring (not illustrated) for supplying a current to the n-electrode is formed in a portion of a surface of the support substrate 50 that the bonding portion 51 covers.

When a current is supplied to the surface emitting laser 10 during driving of the laser device 100, in the semiconductor structure layer 15, heat is generated in a region immediately below the opening 25H through which the current flows into the active layer 19, and heat strain occurs in accordance with the heat. When a stress due to this heat strain is applied to an interface between the semiconductor structure layer 15 and the first multilayer reflector 13, the plane dislocations occur in a region along an upper surface of the uppermost layer of the low refractive-index semiconductor film 13A of the first multilayer reflector 13.

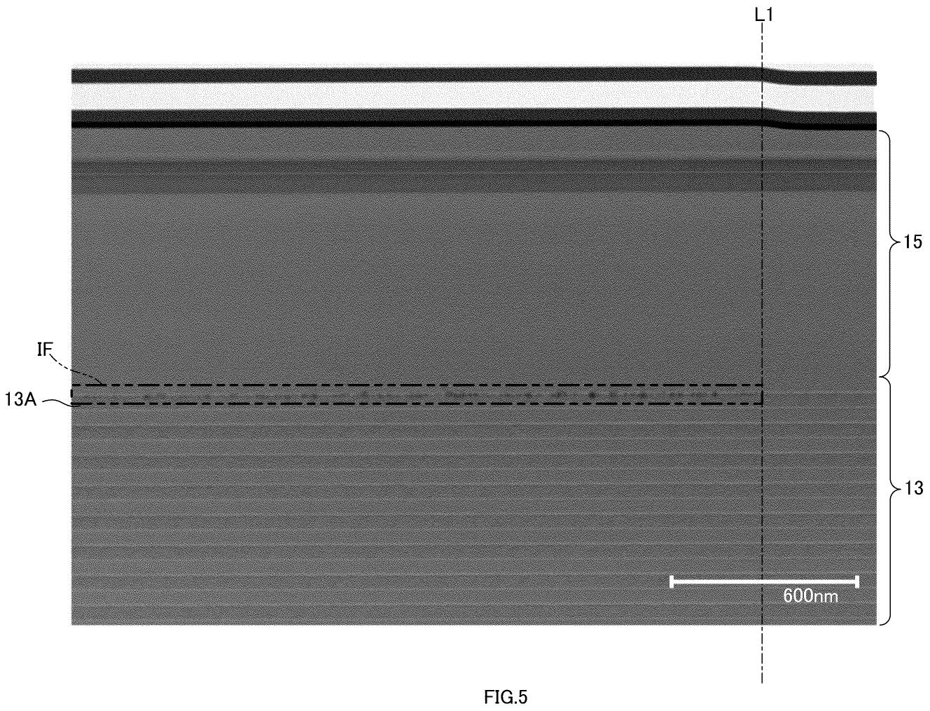

FIG. 5 is a TEM image (50,000 times) of the region A surrounded by the one-dot chain line in FIG. 4, which was imaged after the laser device 100 was driven. In FIG. 5, a straight line L1 is a straight line along the right-edge side surface of the opening 25H in FIG. 4. Accordingly, in FIG. 5, the region at left side with respect to the straight line L1 is the region immediately below the opening 25H.

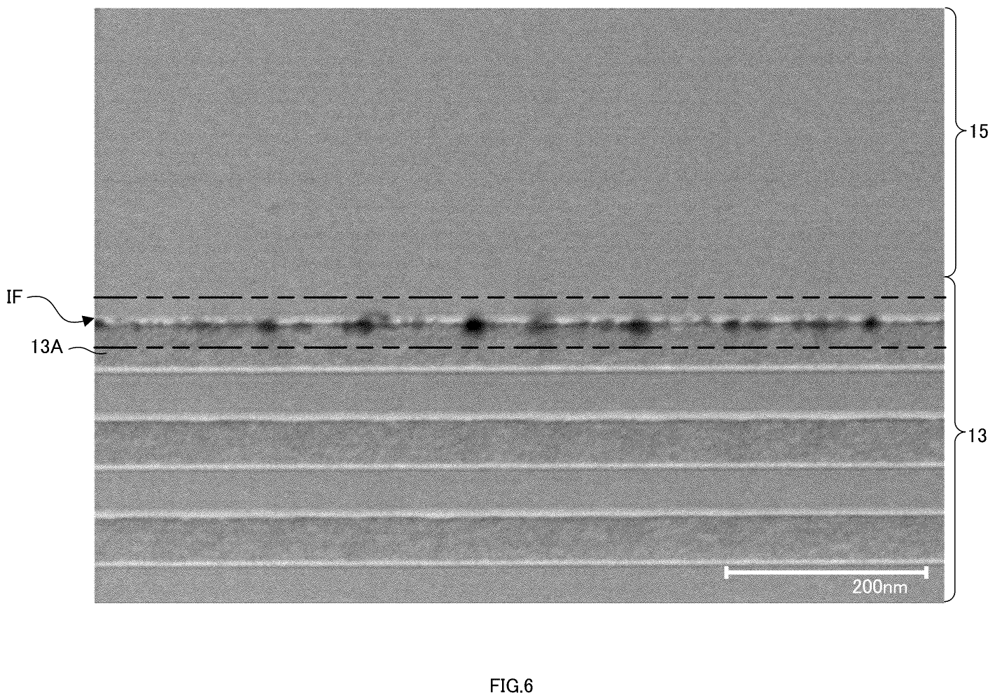

FIG. 6 is a TEM image (150,000 times) in which a part of the region along the interface between the first multilayer reflector 13 and the semiconductor structure layer 15 in FIG. 5 is further enlarged.

As illustrated in FIG. 5 and FIG. 6, after driving of the laser device 100, the plane dislocations (black portions in the figures) are observed in a region IF (the region surrounded by the two-dot chain lines in FIG. 5, and the region sandwiched between the two-dot chain lines in FIG. 6) along the interface between the low refractive-index semiconductor film 13A and the high refractive-index semiconductor film 13B of the first multilayer reflector 13, and at the left side with respect to the straight line L1. In other words, the plane dislocations are formed in the region along the upper surface of the first multilayer reflector 13 and overlapping with the opening 25H when viewed from the normal direction of the upper surface of the substrate 11, that is, the region that overlaps with a region where a current flows in a concentrated manner in the semiconductor structure layer 15. On the other hand, no plane dislocations are formed in the region at the right side with respect to the straight line L1 that does not overlap with the opening 25H when viewed from the normal direction, that is, does not overlap with the region where the current flows in a concentrated manner.

This is because, during driving of the laser device 100, when a current flows in the region immediately below the opening 25H in the semiconductor structure layer 15, heat is generated in that region to generate a strain, and likewise, a stress is applied to the region IF immediately below the opening 25H.

In FIGS. 5 and 6, since both the high refractive-index semiconductor film 13B and the n-type semiconductor layer 17 are made of GaN, the interface cannot be confirmed.

As described above, the region that contains a large quantity of hydrogen as an impurity and is likely to cause the plane dislocations due to stress is formed in an upper portion of the uppermost layer of the low refractive-index semiconductor film 13A of the first multilayer reflector 13.

In particular, since the layer of material having the different lattice constant is formed on its upper surface, the plane dislocations are likely to occur. Since the high refractive-index semiconductor film 13B immediately thereon is as thin as 45 nm (50 nm or less), the influence due to the difference of the lattice constant is also exerted from the n-type semiconductor layer 17, which is formed as thick as 558 nm (500 nm or more). While the n-type semiconductor layer 17 is made of n-GaN in this embodiment, when there is a difference in the lattice constant even when In, Al, and the like of about a few percent are contained, it is still assumed that there is an influence of causing the plane dislocations more likely to occur.

It is thought that the plane dislocations have occurred due to the stress by the above-described strain in the semiconductor layer applied to this region. Also, since almost no plane dislocations has occurred outside the opening 25H where not much heat is generated and not much thermal stress is generated in the semiconductor structure layer 15, it is assumed that plane dislocations are caused by the heat strain and the thermal stress generated in the semiconductor structure layer 15 during driving.

By the generated plane dislocations, during driving, especially during a first driving, the strain and an internal stress generated in the semiconductor structure layer 15 are released, and damage due to the strain is less likely to occur in the semiconductor structure layer 15, especially in the active layer 19. This increases the durability of the surface emitting laser 10.

By the above-described plane dislocations being formed above the uppermost layer of the low refractive-index semiconductor film 13A of the first multilayer reflector 13, the dislocations are suppressed from propagating up to inside the semiconductor structure layer 15 inside the first multilayer reflector 13. Specifically, when the dislocations generated inside the first multilayer reflector 13 propagate toward the semiconductor structure layer 15, bending of the dislocations occurs in a direction along the interface between the low refractive-index semiconductor film 13A and the semiconductor structure layer 15, and the dislocations are suppressed from entering the semiconductor structure layer 15.

Thus, in the surface emitting laser 10, the dislocations generated inside the first multilayer reflector 13 are suppressed from propagating to the semiconductor structure layer 15, specifically up to the active layer 19. This also suppresses the semiconductor structure layer 15 from being damaged and increases the durability of the surface emitting laser 10.

The above-described plane dislocations propagate in equivalent m-axis directions: [1-100], [10-10], [01-10], [−1100], [−1010], [0-110] and in equivalent a-axis directions: [1-210], [−2-1, 2010], [11-20], [−1210], [−2110], [−1-120].

### [Manufacturing Method]

The following describes an example of the method for manufacturing the surface emitting laser 10. First, as the substrate 11, an n-GaN substrate with the c-plane exposed on the upper surface as described above is prepared.

Next, on the upper surface of the substrate 11, an GaN layer (layer thickness 100 nm) is formed as a base layer (not illustrated) using a method of metal organic chemical vapor deposition (MOCVD). Then, a film of 41 pairs of AlInN/GaN layers, that is, the above-described low refractive-index semiconductor films 13A and the high refractive-index semiconductor films 13B is formed on the base layer to form the first multilayer reflector 13.

When forming the first multilayer reflector 13, first, the temperature of a growth substrate is set to 800° C., and a carrier gas is set to N₂. After stabilizing a substrate temperature, trimethyl indium (hereinafter referred to as TMI), trimethyl aluminum (hereinafter referred to as TMA) and NH₃ are supplied, the low refractive-index semiconductor film 13A, which is the AlInN layer, is grown to a thickness of 50 nm on the base layer. Subsequently, the supply of a metal-organic material (hereinafter referred to as an MO material) is stopped. When forming the low refractive-index semiconductor film 13A, the In composition of the AlInN layer, which was the low refractive-index semiconductor film 13A, was set to 18.5 at %.

Subsequently, triethyl gallium (hereinafter referred to as TEG) and NH₃ were supplied, and a cap layer (not illustrated) made of GaN was grown to a thickness of 1 nm on the low refractive-index semiconductor film 13A. Then, the supply of the MO material was stopped. Next, after the carrier gas was changed from N₂ to H₂ and the temperature of the substrate was raised from 800° C. to 1100° C. over 3 minutes, TMG and NH₃ were supplied to form the GaN layer to a thickness of 44 nm, and then by stopping the supply of the MO material, the high refractive-index semiconductor film 13B including the cap layer (not illustrated) was formed.

The first multilayer reflector 13 is formed by repeatedly performing the formation of the low refractive-index semiconductor film 13A and the high refractive-index semiconductor film 13B.

When forming the high refractive-index semiconductor film 13B as the uppermost layer, by setting the carrier gas to H₂ and raising the temperature up to 1100° C. over 3 minutes, high concentration hydrogen is introduced onto the upper surface of the low refractive-index semiconductor film 13A immediately thereunder. As a result, in the region along the interface between the uppermost layer of the low refractive-index semiconductor film 13A and the high refractive-index semiconductor film 13B of the first multilayer reflector 13, a region that contains a large quantity of hydrogen impurities and where the basal plane dislocations are likely to occur as described above is formed.

In order to promote hydrogen uptake such that the region along the interface between the low refractive-index semiconductor film 13A and the high refractive-index semiconductor film 13B becomes a region where the basal plane dislocations are likely to occur, the difference between the growth temperature of the low refractive-index semiconductor film 13A and the growth temperature of the n-type semiconductor layer 17 was set to 250° C. or more. The temperature rising time from the growth temperature of the low refractive-index semiconductor film 13A to the growth temperature of the n-type semiconductor layer 17 was set to 2.5 minutes or more.

Next, the n-type semiconductor layer 17 is formed on the first multilayer reflector 13, specifically on the uppermost layer high refractive-index semiconductor film 13B as the upper surface. TMG, NH₃, and disilane (Si₂H₆) were supplied as material gas to grow Si-doped n-GaN to a thickness of 558 nm.

Next, the active layer 19 is formed by laminating five pairs of layers made of GaInN (layer thickness 3 nm) and GaN (layer thickness 6 nm) on the n-type semiconductor layer 17.

Next, an electronic barrier layer (20 nm) made of Mg-doped AlGaN is formed on the active layer 19 (not illustrated), and then, a film of a p-GaN layer (layer thickness 50 nm) is formed on the electronic barrier layer to form the p-type semiconductor layer 21.

Next, peripheral portions of the p-type semiconductor layer 21, the active layer 19, and the n-type semiconductor layer 17 are etched to form a mesa shape such that the upper surface 17S of the n-type semiconductor layer 17 is exposed in the peripheral portions. In other words, in this step, the semiconductor structure layer 15 having a column shaped portion made of the n-type semiconductor layer 17, the active layer 19, and the p-type semiconductor layer 21 in FIG. 1 is completed.

Next, a peripheral area of the center portion of the upper surface of the p-type semiconductor layer 21 is etched to form the projecting portion 21P. Subsequently, the insulating layer 25 is formed by forming a film of SiO₂ on the semiconductor structure layer 15 and removing a part of the film to form the opening 25H. In other words, SiO₂ is embedded in an etched and removed portion of the upper surface of the p-type semiconductor layer 21.

Next, the transparent electrode 27 is formed by forming a film of ITO of 20 nm on the insulating layer 25, and then, the p-electrode 29 and the n-electrode 23 are formed by forming respective films of Au on the upper surface of the transparent electrode 27 and on the upper surface 17S of the n-type semiconductor layer 17.

Next, a film of Nb₂O₅ of 40 nm is formed as a spacer layer (not illustrated) on the transparent electrode 27, and then, the second multilayer reflector 31 is formed by forming a film of 10.5 pairs of layers made of Nb₂O₅/SiO₂ as one pair on the spacer layer.

When an AR coating is applied to a back surface of the substrate 11, the back surface of the substrate 11 is finally polished, and then, the AR coating made of Nb₂O₅/SiO₂ is formed on the polished surface to complete the surface emitting laser 10.

### Embodiment 2

The following describes a surface emitting laser 70 as Embodiment 2 of the present invention. The surface emitting laser 70 is different from the surface emitting laser 10 of Embodiment 1 in that a tunnel junction structure is formed inside the semiconductor structure layer 15 instead of the insulating layer 25 in order to form the above-described current confinement structure. Specifically, the surface emitting laser 70 is different from the surface emitting laser 10 in the structure above the p-type semiconductor layer 21.

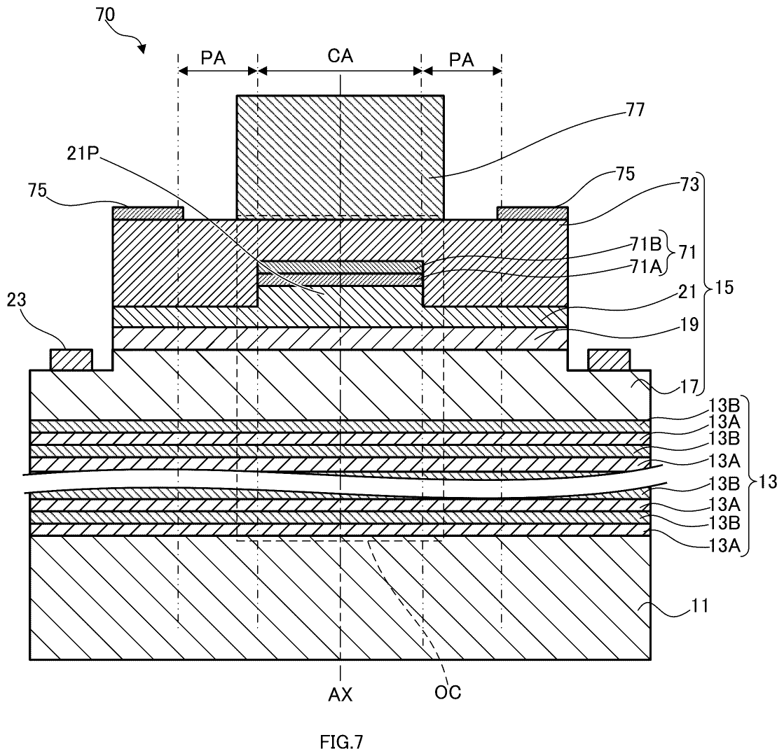

FIG. 7 is a cross-sectional view illustrating a cut surface when the surface emitting laser 70 is cut along a cut line similar to that illustrated in FIG. 1, that is, a cut surface corresponding to FIG. 2. As illustrated in FIG. 7, in the surface emitting laser 70, a tunnel junction layer 71 is formed on the projecting portion 21P of the p-type semiconductor layer 21. That is, in the surface emitting laser 70, the tunnel junction layer 71 is formed in the central region CA inside the semiconductor structure layer 15.

The tunnel junction layer 71 includes: a high dope p-type semiconductor layer 71A that is a p-type semiconductor layer formed on the p-type semiconductor layer 21 and has an impurity concentration higher than that of the p-type semiconductor layer 21; and a high dope n-type semiconductor layer 71B that is an n-type semiconductor layer formed on the high dope p-type semiconductor layer 71A and has an impurity concentration higher than that of the n-type semiconductor layer 17.

An n-type semiconductor layer 73 is formed on the p-type semiconductor layer 21 and the tunnel junction layer 71. The n-type semiconductor layer 73 is formed to embed the tunnel junction layer 71 on the upper surface of the p-type semiconductor layer 21. In other words, the n-type semiconductor layer 73 is formed so as to cover a side surface of the projecting portion 21P as well as a side surface and an upper surface of the tunnel junction layer 71.

The n-type semiconductor layer 73 is an n-type semiconductor layer having a doping concentration similar to that of the n-type semiconductor layer 17. That is, the n-type semiconductor layer 73 has a doping concentration lower than that of the high dope n-type semiconductor layer 71B.

Due to such a laminated structure made of the p-type semiconductor layer 21, the tunnel junction layer 71, and the n-type semiconductor layer 73, a tunneling effect occurs in the tunnel junction layer 71 portion. As a result, in the surface emitting laser 70, a current confinement structure in which a current flows only into the portion of the tunnel junction layer 71 and is confined to the central region CA is formed between the p-type semiconductor layer 21 and the n-type semiconductor layer 73.

A p side electrode 75 is a metal electrode formed along a peripheral edge portion of an upper surface of the n-type semiconductor layer 73. In the surface emitting laser 70, a current flows through the p side electrode 75, the n-type semiconductor layer 73, the tunnel junction layer 71, the p-type semiconductor layer 21, the active layer 19, and the n-type semiconductor layer 17 up to the n-electrode 23.

A second multilayer reflector 77 is formed in a region surrounded by the p side electrode 75 on the upper surface of the n-type semiconductor layer 73 and is a distributed Bragg reflector (DBR) having a configuration similar to that of the second multilayer reflector 31 of the surface emitting laser 10 of Embodiment 1.

Even in such surface emitting laser 70 having the current confinement structure by the tunnel junction layer, as described for the surface emitting laser 10 of Embodiment 1, it is possible to similarly obtain an effect due to a formation of a region where the basal plane dislocations are likely to occur in the first multilayer reflector 13.

In the above-described Embodiment 1, while in order to form the electrical contact surface 21S on the upper surface of the p-type semiconductor layer 21 and an insulating region around the p-type semiconductor layer 21 to form a region where current confinement is generated and a refractive index is low, the insulating layer 25 is disposed, instead of disposing the insulating layer 25, another method may be used to create a region where a current confinement is generated and a refractive index is low.

For example, by etching the upper surface of the p-type semiconductor layer 21 on which the insulating layer 25 is disposed in the above-described embodiments, an insulating region, a region having a low refractive index, and the electrical contact surface 21S may be formed. By performing ion implantation on the upper surface of the p-type semiconductor layer 21 on which the insulating layer 25 is disposed, the insulating region, the region having a low refractive index, and the electrical contact surface 21S may be formed to provide a current confinement effect similar to that of forming the insulating layer 25 in the above-described embodiments. When the ion implantation is performed, for example, B ions, Al ions, or oxygen ions are implanted into the p-type semiconductor layer 21.

In the above-described embodiment, while the uppermost layer of the first multilayer reflector is the GaN layer of the high refractive-index semiconductor film 13B, it may also be the AlInN layer of the low refractive-index semiconductor film 13A. In this case, the plane dislocations occur at the interface between the AlInN layer as the uppermost layer and the n-type semiconductor layer.

Various numerical values, dimensions, materials, and the like in the embodiments described above are merely examples and can be appropriately selected depending on the application and the surface emitting laser to be manufactured.

### DESCRIPTION OF REFERENCE SIGNS

10, 70 . . . surface emitting laser
11 . . . substrate
13 . . . first multilayer reflector
15 . . . semiconductor structure layer
17 . . . n-type semiconductor layer
19 . . . active layer
21 . . . p-type semiconductor layer
23 . . . n-electrode
25 . . . insulating layer
27 . . . transparent electrode
29 . . . p-electrode
31 . . . second multilayer reflector
71 . . . tunnel junction layer
73 . . . n-type semiconductor layer
75 . . . p side electrode
77 . . . second multilayer reflector

1. A vertical cavity light-emitting element comprising:
a gallium-nitride-based semiconductor substrate;
a first multilayer reflector formed on the substrate, the first multilayer reflector being made by an In-containing nitride semiconductor layer containing In in composition and an In-free nitride semiconductor layer including no In being alternately laminated;
a semiconductor structure layer including a first semiconductor layer, an active layer, and a second semiconductor layer, the first semiconductor layer being made of a nitride semiconductor having a first conductivity type formed on the first multilayer reflector, the active layer being made of a nitride semiconductor formed on the first semiconductor layer, the second semiconductor layer being formed on the active layer and made of a nitride semiconductor having a second conductivity type opposite to the first conductivity type;
a second multilayer reflector formed on the semiconductor structure layer, the second multilayer reflector constituting a resonator between the first multilayer reflector and the second multilayer reflector; and
a current confinement structure formed between the first multilayer reflector and the second multilayer reflector, the current confinement structure concentrating a current in one region of the active layer,
wherein a region along an upper surface of the In-containing nitride semiconductor layer formed uppermost in the first multilayer reflector has a higher hydrogen impurity concentration than other regions.

2. The vertical cavity light-emitting element according to claim 1, wherein a portion having a hydrogen impurity concentration of 1E18/cm³ or more is formed in the region along the upper surface of the In-containing nitride semiconductor layer formed uppermost in the first multilayer reflector.

3. The vertical cavity light-emitting element according to claim 1, wherein the In-containing nitride semiconductor layer has AlInN composition, and the In-free nitride semiconductor layer has GaN composition.

4. The vertical cavity light-emitting element according to claim 1, wherein an uppermost layer of the first multilayer reflector is the In-free nitride semiconductor layer.

5. The vertical cavity light-emitting element according to claim 1, wherein an uppermost layer of the first multilayer reflector is the In-containing nitride semiconductor layer.

6. A vertical cavity light-emitting element comprising:
a gallium-nitride-based semiconductor substrate;
a first multilayer reflector formed on the substrate, the first multilayer reflector being made by an In-containing nitride semiconductor layer containing In in composition and an In-free nitride semiconductor layer including no In being alternately laminated;
a semiconductor structure layer including a first semiconductor layer, an active layer, and a second semiconductor layer, the first semiconductor layer being made of a nitride semiconductor having a first conductivity type formed on the first multilayer reflector, the active layer being made of a nitride semiconductor formed on the first semiconductor layer, the second semiconductor layer being formed on the active layer and made of a nitride semiconductor having a second conductivity type opposite to the first conductivity type;
a second multilayer reflector formed on the semiconductor structure layer, the second multilayer reflector constituting a resonator between the first multilayer reflector and the second multilayer reflector; and
a current confinement structure formed between the first multilayer reflector and the second multilayer reflector, the current confinement structure concentrating a current in one region of the active layer,
wherein plane dislocations are formed in a region along an upper surface of the In-containing nitride semiconductor layer formed uppermost in the first multilayer reflector and a region that overlaps with the one region when viewed from a normal direction of an upper surface of the gallium-nitride-based semiconductor substrate.

7. The vertical cavity light-emitting element according to claim 6, wherein the plane dislocations are plane dislocations that have been formed after the vertical cavity light-emitting element has been driven.

8. The vertical cavity light-emitting element according to claim 6, wherein no plane dislocations are formed in the region along the upper surface of the In-containing nitride semiconductor layer formed uppermost in the first multilayer reflector and a region that is free from overlap with the one region when viewed from the normal direction of the upper surface of the gallium-nitride-based semiconductor substrate.

9. The vertical cavity light-emitting element according to claim 7, wherein no plane dislocations are formed in the region along the upper surface of the In-containing nitride semiconductor layer formed uppermost in the first multilayer reflector and a region that is free from overlap with the one region when viewed from the normal direction of the upper surface of the gallium-nitride-based semiconductor substrate.
